(19) United States
(12) Patent Application Publication
(10) Pub. No.: US 2026/0330893 A1
(43) Pub. Date: Oct. 22, 2026

(54) EARLY WARNING METHOD FOR STARTER BATTERY, STORAGE MEDIUM, AND ELECTRONIC DEVICE

(71) Applicant: BYD COMPANY LIMITED, Shenzhen (CN)

(72) Inventors: Hengfeng LI, Shenzhen (CN); Shiwei SHU, Shenzhen (CN); Tianyu FENG, Shenzhen (CN)

(73) Assignee: BYD COMPANY LIMITED, Shenzhen (CN)

(21) Appl. No.: 19/722,695

(22) Filed: Jun. 26, 2026

Related U.S. Application Data
(63) Continuation of application No. PCT/CN2024/109975, filed on Aug. 6, 2024.

(30) Foreign Application Priority Data
Dec. 28, 2023 (CN) 202311851262.4

(51) Int. Cl. G07C 5/00; G01K 3/00; G01K 3/08; G01R 31/371; G01R 31/374; G01R 31/3842; H01M 10/42; H01M 10/48

(52) U.S. Cl. CPC G07C 5/008; G01K 3/005; G01K 3/08; G01R 31/371; G01R 31/374; G01R 31/3842; H01M 10/425; H01M 10/486; H01M 2010/4271; H01M 2220/20

(57) ABSTRACT

In an early warning method for a starter battery, state information data of a starter battery provided by a battery management system of a vehicle is obtained. The state information data includes at least one of voltage data, current data, temperature data and charging data. In the method, whether the starter battery is abnormal is detected based on the state information data. When the starter battery is abnormal, abnormal pre-alarm information is sent to a manufacturer service platform for the starter battery or a user terminal paired with the vehicle. Apparatus and non-transitory computer-readable storage medium counterparts are also contemplated.

### CROSS-REFERENCE TO RELATED APPLICATIONS

The present application is a continuation of International Application No. PCT/CN2024/109975, filed on Aug. 6, 2024, which claims priority to Chinese Patent Application No. 202311851262.4, filed on Dec. 28, 2023, and entitled "EARLY WARNING METHOD FOR STARTER BATTERY, STORAGE MEDIUM AND ELECTRONIC DEVICE." The entire disclosures of the prior applications are hereby incorporated by reference.

### TECHNICAL FIELD

The present disclosure relates to the technical field of battery detection, including an early warning method for a starter battery, a non-transitory computer-readable storage medium, and an electronic device.

### BACKGROUND

The starter battery for starting a vehicle not only supplies power for starting the engine of the vehicle, but also provides required electric energy for other components in the vehicle. Once the starter battery is damaged or aged, the normal operation of devices such as lights, braking systems, and audio equipment can be affected. Therefore, there is a need for a method capable of early discovering signs of starter battery aging, damage, or other faults, so as to take timely measures to deal with them and help ensure the normal operation of the vehicle.

### SUMMARY

The present disclosure includes an early warning method for a starter battery, a non-transitory computer-readable storage medium, and an electronic device to realize timely detection and warning of starter battery anomaly and facilitate timely maintenance of the starter battery.

One or more aspects of the present disclosure provides an early warning method for a starter battery In the method, state information data of the starter battery provided by a battery management system of a vehicle is obtained. The state information data includes at least one of voltage data, current data, temperature data, and charging data. Whether the starter battery is abnormal is detected, by processing circuitry, based on the state information data. When the starter battery is abnormal, abnormal pre-alarm information is sent to a manufacturer service platform of the starter battery and/or a user terminal paired to the vehicle.

According to one embodiment of the present disclosure, before detecting whether the starter battery is abnormal according to the state information data, the state information data is preprocessed. The preprocessing includes at least one of sorting by time, removing null values, removing duplicate data, and removing invalid values.

According to one embodiment of the present disclosure, to detect whether the starter battery is abnormal according to the state information data, a minimum voltage value of the voltage data is determined in a current low voltage detection period. When the minimum voltage value is less than a low voltage pre-alarm threshold, the starter battery is determined to be abnormal.

According to one embodiment of the present disclosure, to detect whether the starter battery is abnormal according to the state information data, the valid voltage values of the voltage data are obtained in a current voltage difference detection period. A voltage frame number of the valid voltage values is counted and a voltage difference average value of the valid voltage values is calculated. When the voltage frame number is greater than a voltage difference pre-alarm frame number and the voltage difference average value is greater than a voltage difference pre-alarm threshold, the starter battery is determined to be abnormal.

According to one or more embodiments of the present disclosure, the plurality of current values in the current data correspond to the plurality of voltage values in the voltage data in a one-to-one manner, and the valid voltage values of the voltage data are obtained in a current voltage difference detection period. A target current value in the current data that is less than a pre-set current threshold is determined, and the voltage value corresponding to the target current value is used as one of the valid voltage values.

According to one or more embodiments of the present disclosure, to calculate a voltage difference average value of the valid voltage values, a minimum value and a maximum value in the valid voltage values are determined. A voltage difference between the maximum value and the minimum value is calculated, and a ratio of the voltage difference to the voltage frame number is used as the voltage difference average value.

According to one or more embodiments of the present disclosure, in-vehicle temperature data and out-of-vehicle temperature data of the vehicle uploaded by the battery management system are obtained. To detect whether the starter battery is abnormal according to the state information data, a valid temperature value is obtained in the temperature data in a current temperature detection period. A temperature frame number of the valid temperature value is counted, and a maximum average temperature difference based on the valid temperature value, the in-vehicle temperature data, and the out-of-vehicle temperature data is obtained. When the temperature frame number is greater than the number of temperature warning frames and the maximum average temperature difference is greater than a temperature pre-alarm threshold, the starter battery is determined to be abnormal.

According to one or more embodiments of the present disclosure, the valid temperature value in the temperature data is obtained in the current temperature detection period, a temperature value greater than a starter battery safety temperature value is obtained in the current temperature detection period and used as the valid temperature value.

According to one or more embodiments of the present disclosure, the plurality of temperature values in the temperature data correspond to the plurality of in-vehicle temperature values in the in-vehicle temperature data and the plurality of out-of-vehicle temperature values in the out-of-vehicle temperature data in a one-to-one manner. To obtain the maximum average temperature difference, a respective first temperature difference between each valid temperature value and a corresponding in-vehicle temperature value is calculated, and a respective second temperature difference between each valid temperature value and a corresponding out-of-vehicle temperature value is calculated. A first mean value (e.g., a first average value) of the first temperature differences and a second mean value (e.g., a second average value) of the second temperature differences is calculated. A greater one of the first mean value and the second mean value is used as the maximum average temperature difference.

According to one or more embodiments of the present disclosure, to detect whether the starter battery is abnormal, an effective charging number in a current charging detection period according to the charging data is obtained. When the effective charging number is greater than a charging number pre-alarm threshold, the starter battery is determined to be abnormal.

According to one or more embodiments of the present disclosure, the charging data includes a charging time and a starter battery voltage at the end of each charging (e.g., each effective charging process). The effective charging process corresponds to a charging process with a charging time greater than a pre-set charging time threshold and a starter battery voltage at the end of charging reaching a pre-set charging voltage threshold.

One or more aspects of the present disclosure provides a non-transitory computer-readable storage medium which has a computer program stored thereon, which when executed by processing circuitry (e.g., a processor), cause the processing circuitry to perform the early warning method of the starter battery according to one or more examples of the present disclosure.

One or more aspects of the present disclosure provides an electronic device, including a memory (e.g., including a non-transitory computer-readable storage medium), processing circuitry (e.g., a processor), and a computer program stored on the memory. The computer program, when executed by processing circuitry (e.g., the processor), cause the processor to perform the early warning method of the starter battery according to one or more examples of the present disclosure.

According to one or more embodiments of the present disclosure, firstly the state information data of the starter battery is obtained, then whether the starter battery is abnormal according to the state information data is detected, when the starter battery is abnormal, the abnormal pre-alarm information can be sent to the manufacturer service platform of the starter battery and/or the user terminal paired with the vehicle. Therefore, the starter battery anomaly can be detected and warned in time, and the starter battery can be maintained in time.

Additional examples of aspects and advantages of the present disclosure are set forth in the following description.

### BRIEF DESCRIPTION OF THE DRAWINGS

FIG. 1 is a flow chart of an early warning method of the starter battery according to an embodiment of the present disclosure;

FIG. 2 is a flow chart of an early warning method of the starter battery according to an embodiment of the present disclosure;

FIG. 3 is a system schematic implementing the early warning method of the starter battery according to an embodiment of the present disclosure; and

FIG. 4 is a structural schematic of an electronic device according to an embodiment of the present disclosure.

### DETAILED DESCRIPTION

Descriptions of terms in this disclosure are provided as examples only and are not intended to limit the scope of the disclosure.

One or more embodiments of the present disclosure are described in further detail below, examples are shown in the drawings, in which the same or similar reference numerals represent the same or similar elements or elements having the same or similar functions throughout. One or more embodiments described below by referring to the drawings are non-limiting examples and are intended to explain the present disclosure, and should not be understood as a limitation on the scope of the present disclosure.

One or more embodiments of an early warning method of the starter battery, a non-transitory computer-readable storage medium, and an electronic device of the present disclosure are described below with reference to the drawings.

FIG. 1 is a flow chart of the early warning method of the starter battery according to an embodiment of the present disclosure.

As shown in FIG. 1, the early warning method of the starter battery comprises:

S11, obtaining the state information data of the starter battery provided (e.g., uploaded) by a battery management system of a vehicle. The state information data comprises at least one of voltage data, current data, temperature data, and charging data.

In one or more embodiments, the voltage data, the current data, the temperature data, the charging data of the starter battery etc. can be obtained by a BMS (Battery Management System) of the vehicle. After obtaining the data, the BMS can upload the above state information data to an electronic device, such as a cloud server etc., in the form of data frames at a pre-set time interval, the electronic device executes the early warning method of the starter battery in one or more embodiments of the present disclosure. Hereinafter, the cloud server is taken as an example for description.

S12, detecting whether the starter battery is abnormal according to the state information data.

In some embodiments of the present disclosure, when the state information data comprises the voltage data, the detecting whether the starter battery is abnormal according to the state information data, comprises: determining a minimum voltage value of the voltage data in a current low voltage detection period. When the minimum voltage value is less than a low voltage pre-alarm threshold, the starter battery is determined to be abnormal.

In one or more embodiments, the cloud server can perform low voltage anomaly detection once every other low voltage detection period. The low voltage anomaly detection can be performed by a low voltage anomaly detection module. In the current low voltage detection period, the low voltage anomaly detection module compares the minimum voltage value of the voltage data in the current low voltage detection period with the low voltage pre-alarm threshold. The starter battery is determined to have a low voltage anomaly when the minimum voltage value is less than the low voltage pre-alarm threshold. The low voltage detection period is greater than the pre-set time interval.

In some embodiments of the present disclosure, when the state information data comprises the voltage data, the detecting whether the starter battery is abnormal according to the state information data, comprises: screening for valid voltage values of the voltage data in a current voltage difference detection period; counting the number of voltage frames of the valid voltage values, calculating a voltage difference average value of the valid voltage values; determining that the starter battery is abnormal when the number of voltage frames is greater than a voltage difference pre-alarm frame number, while the voltage difference average value is greater than a voltage difference pre-alarm threshold.

In at least one embodiment, the cloud server can perform voltage difference anomaly detection once every other voltage difference detection period, and the voltage difference anomaly detection can be performed by a voltage difference anomaly detection module. In the current voltage difference detection period, the voltage difference anomaly detection module screens out the valid voltage values of the voltage data in the current voltage difference detection period; counts the number of voltage frames (i.e., the number of corresponding data frames) of the valid voltage values, and calculates the voltage difference average value of the valid voltage values; and determines that the starter battery is in a voltage difference anomaly when the number of voltage frames is greater than a voltage difference pre-alarm frame number, while the voltage difference average value is greater than a voltage difference pre-alarm threshold. The voltage difference detection period is greater than the pre-set time interval and can be equal to the low voltage anomaly detection period.

In some aspects, the voltage difference anomaly detection module can directly subtract the maximum value from the minimum value in the valid voltage values, compare the difference with a corresponding voltage difference pre-alarm threshold (which is different from the voltage difference pre-alarm threshold compared with the voltage difference average value), and determine that the starter battery is in a voltage difference anomaly when the difference is greater than the voltage difference pre-alarm threshold. Compared with the comparison of the voltage difference average value and the number of voltage frames, the voltage difference is compared only, the calculation complexity is low, but the reliability is also low.

In some embodiments of the present disclosure, the state information data further comprises current data, a plurality of current values in the current data correspond to a plurality of voltage values in the voltage data in a one-to-one manner, and the valid voltage values in the voltage data in the current voltage difference detection period are screened out by: determining a target current value in the current data that is less than a pre-set current threshold; and taking a voltage value corresponding to the target current value as one of the valid voltage values.

In at least one embodiment, in order to improve the accuracy of voltage difference anomaly detection, voltage data susceptible to current can be first removed, mainly voltage values corresponding to current values greater than a pre-set current threshold. For example, when the charging current of the starter battery is large, the voltage of the starter battery is unstable. Based on this, the valid voltage value can be a voltage value corresponding to a target current value less than the pre-set current threshold in the current data. Using the valid voltage value for voltage difference anomaly detection can improve the accuracy and reliability of detection.

In some embodiments of the present disclosure, calculating the voltage difference average value of the valid voltage values can comprise: determining a minimum value and a maximum value in the valid voltage values; calculating a voltage difference between the maximum value and the minimum value; and taking a ratio of the voltage difference to the voltage frame number as the voltage difference average value.

In at least one embodiment, after the voltage data susceptible to current is removed, the voltage difference average value of the valid voltage data can be calculated. The calculation formula can be Vmean=(Vmax-Vmin)/voltage frame number. Vmean is compared with the voltage difference pre-alarm threshold, and the voltage frame number corresponding to the valid voltage value is compared with the voltage difference pre-alarm frame number. When Vmean is greater than the voltage difference pre-alarm threshold and the voltage frame number corresponding to the valid voltage value is greater than the voltage difference pre-alarm frame number, the starter battery is determined to have a voltage difference anomaly.

In some embodiments of the present disclosure, when the state information data comprises temperature data, the method further comprises: obtaining in-vehicle temperature data and out-of-vehicle temperature data uploaded by the battery management system. The detecting whether the starter battery has an anomaly according to the state information data comprises: screening for valid temperature values in the temperature data in the current temperature detection period; counting a temperature frame number of the valid temperature values, and obtaining a maximum average temperature difference according to the valid temperature values, the in-vehicle temperature data, and the out-of-vehicle temperature data; and when the temperature frame number is greater than a temperature pre-alarm frame number, while the maximum average temperature difference is greater than a temperature pre-alarm threshold, determining that the starter battery has an anomaly.

In at least one embodiment, the BMS can upload the in-vehicle temperature data and the out-of-vehicle temperature data to the cloud server in the form of data frames with the state information of the starter battery together. The cloud server can perform temperature anomaly detection once every other temperature detection period. The temperature anomaly detection can be performed by a temperature anomaly detection module. In the current temperature detection period, the temperature anomaly detection module screens out valid temperature values of the temperature data in the current temperature detection period; counts the temperature frame number (i.e., the corresponding data frame number) of the valid temperature values, and obtains a maximum average temperature difference according to the valid temperature values, the in-vehicle temperature data, and the out-of-vehicle temperature data; and when the temperature frame number is greater than a temperature warning frame number and the maximum average temperature difference is greater than a temperature pre-alarm threshold, determines that the starter battery has a temperature anomaly. The temperature detection period is greater than the pre-set time interval and can be equal to the low voltage anomaly detection period and the voltage difference anomaly detection period.

In some embodiments of the present disclosure, screening for the valid temperature values in the temperature data in the current temperature detection period comprises: screening for temperature values greater than a safe temperature value of the starter battery in the current temperature detection period as the valid temperature values.

In at least one embodiment, in order to improve the accuracy of temperature anomaly detection, the temperature values greater than the safe temperature value of the starter battery can be used as the valid temperature values for temperature anomaly detection.

In some embodiments of the present disclosure, the plurality of temperature values of the temperature data correspond to the plurality of in-vehicle temperature values of the in-vehicle temperature data and the plurality of out-of-vehicle temperature values of the out-of-vehicle temperature data in a one-to-one manner. Obtaining the maximum average temperature difference according to the valid temperature values, the in-vehicle temperature data, and the out-of-vehicle temperature data, comprises: calculating a first temperature difference between each valid temperature value and a corresponding in-vehicle temperature value respectively, and calculating a second temperature difference between each valid temperature value and a corresponding out-of-vehicle temperature value respectively; calculating a first average value of the first temperature differences and a second average value of the second temperature differences; and taking a greater one of the first average value and the second average value as the maximum average temperature difference.

In at least one embodiment, after screening for the temperature values greater than the safe temperature value of the starter battery of the temperature data in the current temperature detection period as the valid temperature values, the average temperature differences between the valid temperature values and the in-vehicle temperature and the out-of-vehicle temperature are calculated respectively, and the maximum value of the two average temperature differences is used to compare the temperature difference threshold, that is, Tmean = max(mean(Tstarter battery - Tin-vehicle temperature), mean(Tstarter battery - Tout-vehicle temperature)). The temperature data in the starter battery parameters are compared with the temperature anomaly pre-alarm threshold, and the comparison information comprises the maximum average temperature difference of the starter battery temperature, the in-vehicle temperature and the out-of-vehicle temperature, and the temperature frame number corresponding to the valid temperature values. When the maximum average temperature difference is greater than the temperature pre-alarm threshold and the temperature frame number is greater than the temperature pre-alarm frame number, the starter battery is determined to have a temperature anomaly.

In some embodiments of the present disclosure, when the state information data comprises charging data, detecting whether the starter battery has an anomaly according to the state information data comprises: obtaining the valid charging number in the current charging detection period according to the charging data; and when the valid charging number is greater than a charging number pre-alarm threshold, determining that the starter battery has an anomaly.

In this embodiment, the charging data comprises a charging time of each charging and a starter battery voltage at the end of each charging, the effective charging may refer to a charging process in which the charging time is greater than a pre-set charging time threshold and the starter battery voltage at the end of the charging reaches a pre-set charging voltage threshold.

In at least one embodiment, the cloud server can perform charging anomaly detection once every other charging detection period. The charging anomaly detection can be performed by a charging anomaly detection module. In a certain time window (i.e., a certain charging detection period), the charging anomaly detection module can count the number of effective charging times of the starter battery. The standard for effective charging is that the charging time and the terminal voltage of charging both reach corresponding thresholds. The number of effective charging times in the time window is compared with a charging number pre-alarm threshold. When the number of effective charging times is greater than the charging number pre-alarm threshold, the starter battery is determined to have a charging anomaly.

In some embodiments of the present disclosure, before detecting whether the starter battery has anomaly according to the state information data, the method further comprises: preprocessing the state information data. The preprocessing comprises at least one of sorting by time, removing null values, removing duplicate data, and removing invalid values.

In at least one embodiment, due to noise influence or interference in the process of data acquisition, transmission, etc., null values, duplicate data, invalid values, etc. can appear in the state information data acquired by the cloud server. To improve the accuracy and reliability of starter battery anomaly detection, the state information data can be processed to remove null values, duplicate data, invalid values, etc. before anomaly detection. Meanwhile, to facilitate determination of the detection timing of starter battery anomaly detection, the state information data can be time sorted. After the preprocessing such as sorting by time, null value removal, duplicate data removal, invalid value removal, etc. is performed, the preprocessed data can be input into each anomaly detection module. The anomaly detection modules comprise the low voltage anomaly detection module, the voltage difference anomaly detection module, the temperature anomaly detection module, and the charging anomaly detection module. Different detection modules are configured with different pre-alarm thresholds, and each threshold is determined according to historical starter battery parameters.

S13, when the starter battery is abnormal, sending abnormal pre-alarm information to a manufacturer service platform of the starter battery and/or a user terminal paired with the vehicle to issue the abnormal pre-alarm information.

In at least one embodiment, when each anomaly detection module detects a starter battery anomaly, the cloud server can send corresponding abnormal pre-alarm information to the manufacturer service platform of the starter battery and/or the user terminal paired with the vehicle, for example, when the starter battery has low voltage anomaly, sending abnormal pre-alarm information containing the low voltage anomaly, so that the manufacturer or the vehicle owner can timely maintain the starter battery.

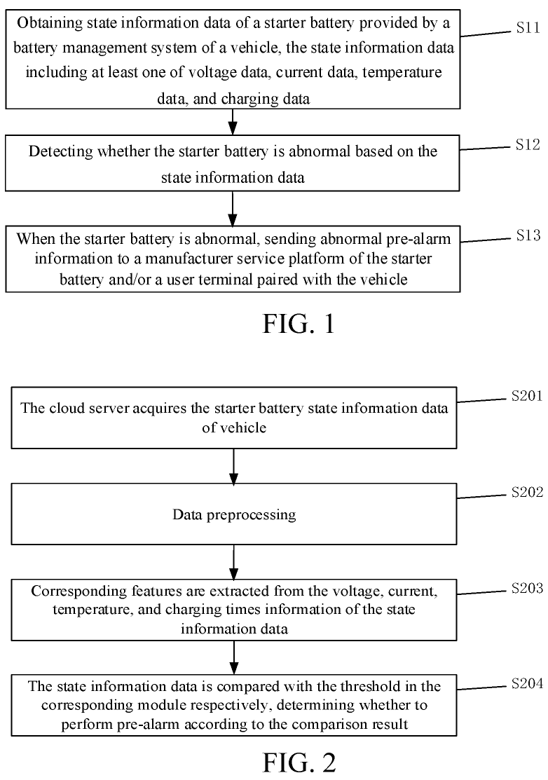

To facilitate understanding, the following describes an early warning method of the starter battery of an embodiment of the present disclosure in combination with FIG. 2.

As shown in FIG. 2, the early warning method of the starter battery comprises:

S201, the cloud server acquires the starter battery state information data of the vehicle.

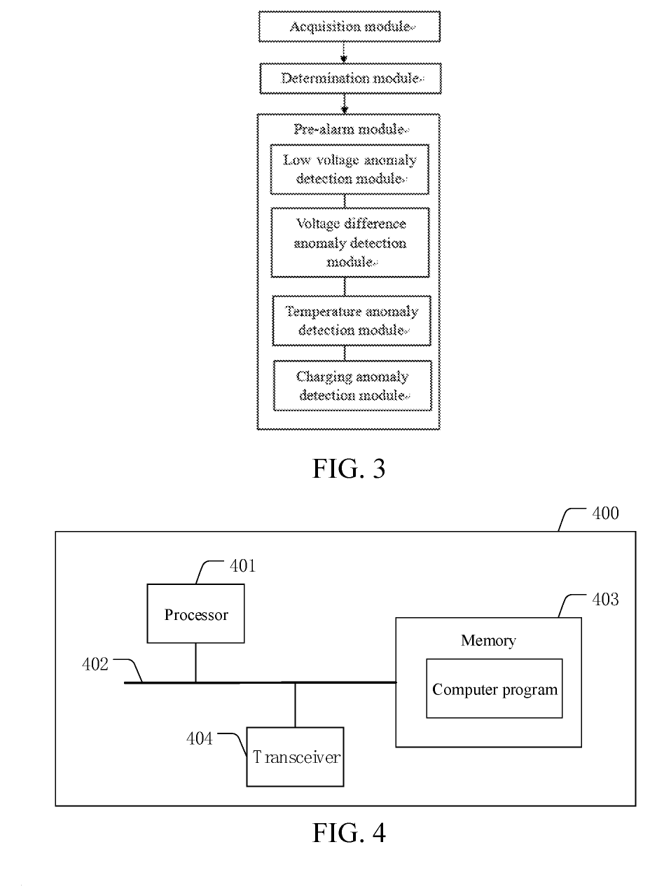

In at least one embodiment, this flow measures the state information data such as the voltage, current, temperature, and charging times of the starter battery, and uploads the data to the cloud server through the BMS system. At this time, the state information data can be acquired by the acquisition module in the cloud server shown in FIG. 3.

S202, data preprocessing.

S203, corresponding features are extracted from the voltage, current, temperature, and charging times information of the state information data.

In at least one embodiment, the uploaded state information such as the voltage, current, temperature, and charging times of the starter battery is used to monitor voltage anomaly, self-discharge anomaly, temperature anomaly, and charging anomaly of the starter battery, and to perform multi-faceted pre-alarm on the starter battery.

S204, the state information data is compared with the threshold in the corresponding module respectively, determining whether to perform pre-alarm according to the comparison result.

In at least one embodiment, after the acquisition module acquires the state information data, the determination module in the cloud server shown in FIG. 3 can preprocess and extract features from the state information data, and then send the extracted features to the corresponding anomaly detection module (including the low voltage anomaly detection module, the voltage difference anomaly detection module, the temperature anomaly detection module, and the charging anomaly detection module) in the pre-alarm module. Determining whether the corresponding pre-alarm item exceeds the pre-alarm threshold by each anomaly detection module, and pre-alarm is performed when it does. When pre-alarm is performed, the cloud server can send the pre-alarm information to the manufacturer and the customer at the first time, so as to remind the customer to replace the starter battery in time through the manufacturer, or directly remind the customer to replace the starter battery in time. Meanwhile, the manufacturer can also optimize the production of the starter battery according to the pre-alarm information issued for the starting batteries of different vehicles, so as to improve the health status of subsequent starting batteries.

The pre-alarm method for the starter battery in one or more embodiments of the present disclosure, the state information data of the starter battery is uploaded to the cloud server through the BMS system. Each anomaly detection module in the cloud server performs anomaly pre-alarm on the starter battery by using the uploaded state information such as the voltage, current, temperature, and charging times of the starter battery, and when pre-alarm is needed, the cloud server can send the abnormal pre-alarm information to the manufacturer and the customer at the first time, so as to replace the starter battery in time and help ensure the normal operation of the vehicle.

Based on the above-mentioned early warning method of the starter battery, the present disclosure further provides a non-transitory computer-readable storage medium.

In this embodiment, a computer program is stored thereon, and when executed by a processor, the computer program implements an early warning method for the starter battery based on one or more embodiments of this disclosure.

Based on the above-mentioned early warning method of the starter battery, the present disclosure further provides an electronic device or a processing apparatus.

FIG. 4 is a structural schematic of a processing apparatus such as an electronic device according to an embodiment of the present disclosure.

As shown in FIG. 4, the electronic device 400 comprises processing circuitry, such as a processor 401, a memory 403, and a computer program stored on the memory, and when executed by the processor, the computer program implements the above-mentioned early warning method of the starter battery.

The processing circuitry, such as the processor 401, can be a CPU (Central Processing Unit), a general purpose processor, a DSP (Digital Signal Processor), an ASIC (Application Specific Integrated Circuit), an FPGA (Field Programmable Gate Array) or other programmable logic device, a transistor logic device, a hardware component, or any combination thereof. The processor 401 can implement or execute various example logical blocks, modules, and circuits described in connection with the present disclosure. The processor 401 can also be implemented or performed by a combination of computing logic, such as a combination of one or more microprocessors, a combination of a DSP and a microprocessor, or the like.

The bus 402 can comprise a path that permits information to be transferred from one component of the apparatus to another. The bus 402 can be a PCI (Peripheral Component Interconnect), EISA (Extended Industry Standard Architecture) or another bus. The bus 402 can be divided into an address bus, a data bus, a control bus, etc. One thick line in FIG. 4 is merely used for convenience of representation, but is not intended to represent that only one bus or one type of bus exists.

The memory 403 includes a non-transitory computer-readable storage medium that is configured to store a computer program corresponding to the early warning method for starting a battery in one or more embodiments of the present disclosure. The processor 401 is configured to execute the computer program stored in the memory 403 to implement the content shown in the foregoing method embodiments.

The electronic device 400 comprises, but is not limited to, a mobile terminal such as a mobile phone, a laptop computer, a digital broadcasting receiver, a PDA (Personal Digital Assistant), a PAD (Personal Digital Assistant), a PMP (Portable Multimedia Player), a vehicle terminal, and a stationary terminal such as a cloud server, a digital TV, and a desktop computer. The electronic device 400 shown in FIG. 4 is merely an example, and should not impose any limitation on the function and use range of the present disclosure.

Note that, logic and/or steps represented in flow charts or otherwise described herein, for example, can be considered a sequence listing of executable instructions for implementing logical functions, may be embodied in any computer readable medium, for use by an instruction execution system, apparatus, or device, such as a computer-based system, processor-including system, or other system that can fetch the instructions from the instruction execution system, apparatus, or device and execute the instructions, or used in connection with these instruction execution systems, apparatus, or devices. In the case of the present disclosure, a "computer-readable medium" can be any apparatus that can contain, store, communicate, propagate, or transport the program for use by or in connection with the instruction execution system, apparatus, or device. More specific examples (a non-exhaustive list) of the computer-readable medium include the following: an electrical connection (electronic device) including one or more wirings, a portable computer tray (magnetic device), a random access memory (RAM), a read-only memory (ROM), an erasable editable read-only memory (EPROM or Flash memory), an optical fiber device, and a portable compact disc read-only memory (CDROM). The computer readable medium could even be paper or other suitable medium onto which the program can be printed, as the program can be electronically obtained, for example, by optically scanning the paper or other medium, followed by editing, interpreting, or otherwise processing in a suitable manner as necessary, and then stored in a computer memory.

It should be understood that portions of the present disclosure can be implemented in hardware, software, firmware, or a combination thereof. In the above embodiments, the plurality of steps or methods can be implemented in software or firmware stored in a memory and executed by a suitable instruction execution system. For example, if implemented in hardware, as in another embodiment, this can be accomplished with any or a combination of the following technologies: a discrete logic circuit having logic gates for implementing logic functions upon data signals, an application specific integrated circuit having appropriate combinational logic gates, a programmable gate array (PGA), a field programmable gate array (FPGA), etc.

In the description of the disclosure, reference to terms such as "an embodiment", "some embodiments", "an example", "a specific example" or "some examples" etc., mean that the particular feature(s), structure(s), material(s) or characteristic(s) described in connection with one or more embodiments or examples is comprised in at least one embodiment or example of the disclosure. The appearances of such terms in various places of the disclosure are not necessarily all referring to the same embodiment or example. Moreover, described features, structures, materials, or characteristics can be combined in any suitable manner in one or more embodiments or examples.

In the description of the present disclosure, it is to be understood that the terms "center", "longitudinal", "transverse", "length", "width", "thickness", "upper", "lower", "front", "rear", "left", "right", "vertical", "horizontal", "top", "bottom", "inner", "outer", "clockwise", "counterclockwise", "axial", "radial", "circumferential" and the like indicate the orientation or positional relationship based on the orientation or positional relationship shown in the drawings, and are for the convenience of describing the present disclosure and simplifying the description, and do not indicate or imply that the device or element referred to has a particular orientation, or is constructed and operated in a particular orientation, and therefore should not be understood as a limitation on the present disclosure.

In addition, the terms "first", "second", and the like are used herein for descriptive purposes only and are not intended to indicate or imply relative importance or a number of indicated technical features. Thus, features defined with "first", "second" can comprise at least one of the features explicitly or implicitly. In the description of the present disclosure, the meaning of "a plurality of" is at least two, for example, two, three, and the like, unless otherwise explicitly and specifically defined.

In the present disclosure, unless otherwise clearly specified and limited, the terms "mounting", "connecting", "fixing" and the like should be understood in a broad sense, for example, can be fixed connection, can also be detachable connection, or integral; can be mechanical connection, can also be electrical connection; can be directly connected, can also be indirectly connected through an intermediate medium, can be the internal communication of two elements or the interaction relationship of two elements, unless otherwise clearly defined. For those of ordinary skill in the art, the specific meanings of the above terms in the present disclosure can be understood according to the specific circumstances.

In the present disclosure, unless otherwise clearly specified and limited, the first feature "on" or "under" the second feature can be that the first and second features are in direct contact, or the first and second features are in indirect contact through an intermediate medium. Moreover, the first feature "on", "above" and "over" the second feature can be that the first feature is directly above or obliquely above the second feature, or only indicates that the horizontal height of the first feature is higher than that of the second feature. The first feature "under", "below" and "under" the second feature can be that the first feature is directly below or obliquely below the second feature, or only indicates that the horizontal height of the first feature is less than that of the second feature.

As used herein, “at least one of A, B, or C” refers to any one or more of the listed elements (e.g., A alone, B alone, C alone, A and B, A and C, B and C, or A, B, and C). Similarly, “one of A and B” includes A, B, or both A and B.

As used herein, modules, submodules, and units described in this disclosure may be implemented by processing circuitry, software stored on a non-transitory computer-readable storage medium, or a combination thereof. Software modules may include instructions executed by processing circuitry such as one or more processors. Memory or other storage may store the software modules, and the relationship between software modules, hardware modules, processors, and memory may vary depending on the implementation.

Although the above has shown and described one or more embodiments of the present disclosure, it is to be understood that the above embodiments are non-limiting examples and should not be understood as a limitation on the present disclosure. Those of ordinary skill in the art can make changes, modifications, replacements, or variations to one or more embodiments described in this disclosure, and such changes, modifications, replacements, or variations are within the scope of the present disclosure.

What is claimed is:

1. An early warning method for a starter battery, comprising:
obtaining state information data of the starter battery provided by a battery management system of a vehicle, the state information data including at least one of voltage data, current data, temperature data, and charging data;
detecting, by processing circuitry, whether the starter battery is abnormal based on the state information data; and
when the starter battery is abnormal, sending abnormal pre-alarm information to a manufacturer service platform of the starter battery and/or a user terminal paired with the vehicle.

2. The early warning method according to claim 1, further comprising:
preprocessing the state information data, the preprocessing including at least one of sorting by time, removing null values, removing duplicate data, and removing invalid values.

3. The early warning method according to claim 1, wherein the detecting whether the starter battery is abnormal comprises:
determining a minimum voltage value in the voltage data in a current low voltage detection period; and
when the minimum voltage value is less than a low voltage pre-alarm threshold, determining that the starter battery is abnormal.

4. The early warning method according to claim 1, wherein the detecting whether the starter battery is abnormal comprises:
obtaining valid voltage values of the voltage data in a current voltage difference detection period;
counting a voltage frame number of the valid voltage values;
calculating a voltage difference average of the valid voltage values; and
when the voltage frame number is greater than a voltage difference pre-alarm frame number and the voltage difference average is greater than a voltage difference pre-alarm threshold, determining that the starter battery is abnormal.

5. The early warning method according to claim 4, wherein
a plurality of current values of the current data corresponds to a plurality of voltage values of the voltage data in a one-to-one manner; and
the obtaining the valid voltage values includes determining a target current value in the current data that is less than a pre-set current threshold, a voltage value corresponding to the target current value being one of the valid voltage values.

6. The early warning method according to claim 4, wherein the calculating the voltage difference average comprises:
determining a minimum value and a maximum value in the valid voltage values;
calculating a voltage difference between the maximum value and the minimum value; and
determining the voltage difference average as a ratio of the voltage difference to the voltage frame number.

7. The early warning method according to claim 1, further comprising:
obtaining in-vehicle temperature data and out-of-vehicle temperature data of the vehicle provided by the battery management system,
wherein the detecting whether the starter battery is abnormal includes:
obtaining valid temperature values of the temperature data in a current temperature detection period;
counting a temperature frame number of the valid temperature values;
obtaining a maximum average temperature difference based on the valid temperature values, the in-vehicle temperature data, and the out-of-vehicle temperature data; and
determining that the starter battery is abnormal when the temperature frame number is greater than a temperature pre-alarm frame number and the maximum average temperature difference is greater than a temperature pre-alarm threshold.

8. The early warning method according to claim 7, wherein the obtaining the valid temperature values comprises:
obtaining temperature values greater than a starter battery safety temperature value in the current temperature detection period as the valid temperature values.

9. The early warning method according to claim 7, wherein
a plurality of temperature values of the temperature data corresponds to a plurality of in-vehicle temperature values of the in-vehicle temperature data and a plurality of out-of-vehicle temperature values of the out-of-vehicle temperature data in a one-to-one manner; and
the obtaining the maximum average temperature difference includes:
calculating a respective first temperature difference between each of the valid temperature values and a corresponding in-vehicle temperature value;
calculating a respective second temperature difference between each of the valid temperature values and a corresponding out-of-vehicle temperature value;
calculating a first average of the first temperature differences and a second average of the second temperature differences; and
obtaining a greater one of the first average and the second average as the maximum average temperature difference.

10. The early warning method according to claim 1, wherein the detecting whether the starter battery is abnormal comprises:
obtaining an effective charging number in a current charging detection period based on the charging data; and
determining that the starter battery is abnormal when the effective charging number is greater than a charging number pre-alarm threshold.

11. The early warning method according to claim 10, wherein
the charging data includes a charging time and a starter battery voltage at an end of each effective charging process; and
each effective charging process is associated with a charging time that is greater than a pre-set charging time threshold and a starter battery voltage at the end of the charging process that reaches a pre-set charging voltage threshold.

12. A processing apparatus, comprising:
processing circuitry configured to:
obtain state information data of a starter battery provided by a battery management system of a vehicle, the state information data including at least one of voltage data, current data, temperature data, and charging data;
detect whether the starter battery is abnormal based on the state information data; and
when the starter battery is abnormal, send abnormal pre-alarm information to a manufacturer service platform of the starter battery and/or a user terminal paired with the vehicle.

13. The apparatus according to claim 12, wherein the processing circuitry is configured to:
preprocess the state information data, the preprocessing including at least one of sorting by time, removing null values, removing duplicate data, and removing invalid values.

14. The apparatus according to claim 12, wherein the processing circuitry is configured to:
determine a minimum voltage value in the voltage data in a current low voltage detection period; and
when the minimum voltage value is less than a low voltage pre-alarm threshold, determine that the starter battery is abnormal.

15. The apparatus according to claim 12, wherein the processing circuitry is configured to:
obtain valid voltage values of the voltage data in a current voltage difference detection period;
count a voltage frame number of the valid voltage values;
calculate a voltage difference average of the valid voltage values; and
when the voltage frame number is greater than a voltage difference pre-alarm frame number and the voltage difference average is greater than a voltage difference pre-alarm threshold, determine that the starter battery is abnormal.

16. The apparatus according to claim 15, wherein
a plurality of current values of the current data corresponds to a plurality of voltage values of the voltage data in a one-to-one manner; and
the processing circuitry is configured to:
determine a target current value in the current data that is less than a pre-set current threshold, a voltage value corresponding to the target current value being one of the valid voltage values.

17. The apparatus according to claim 15, wherein the processing circuitry is configured to:
determine a minimum value and a maximum value in the valid voltage values;
calculate a voltage difference between the maximum value and the minimum value; and
determine the voltage difference average as a ratio of the voltage difference to the voltage frame number.

18. The apparatus according to claim 12, wherein the processing circuitry is configured to:
obtain in-vehicle temperature data and out-of-vehicle temperature data of the vehicle provided by the battery management system;
obtain valid temperature values of the temperature data in a current temperature detection period;
count a temperature frame number of the valid temperature values;
obtain a maximum average temperature difference based on the valid temperature values, the in-vehicle temperature data, and the out-of-vehicle temperature data; and
determine that the starter battery is abnormal when the temperature frame number is greater than a temperature pre-alarm frame number and the maximum average temperature difference is greater than a temperature pre-alarm threshold.

19. The apparatus according to claim 12, wherein the processing circuitry is configured to:
obtain an effective charging number in a current charging detection period based on the charging data; and
determine that the starter battery is abnormal when the effective charging number is greater than a charging number pre-alarm threshold.

20. A non-transitory computer-readable storage medium storing instructions which, when executed by at least one processor, cause the at least one processor to perform an early warning method for a starter battery, the method comprising:
obtaining state information data of the starter battery provided by a battery management system of a vehicle, the state information data including at least one of voltage data, current data, temperature data, and charging data;
detecting whether the starter battery is abnormal based on the state information data; and
when the starter battery is abnormal, sending abnormal pre-alarm information to a manufacturer service platform of the starter battery and/or a user terminal paired with the vehicle.
